(19) United States
(12) Patent Application Publication
(10) Pub. No.: US 2026/0068766 A1
(43) Pub. Date: Mar. 5, 2026

(54) OPTICAL MODULE

(71) Applicant: SHINKO ELECTRIC INDUSTRIES CO., LTD., Nagano-shi (JP)

(72) Inventor: Masaki MATSUMOTO, Nagano-shi (JP)

(21) Appl. No.: 19/304,195

(22) Filed: Aug. 19, 2025

(30) Foreign Application Priority Data
Aug. 28, 2024 (JP) 2024-146392

(51) Int. Cl. H01L 25/16; G02B 6/42; H01L 21/48; H01L 21/66; H01L 23/00; H01L 23/13; H01L 23/18; H01L 23/498; H01L 23/538; H01L 25/00

(52) U.S. Cl. CPC H01L 25/167; G02B 6/4251; G02B 6/4274

(57) ABSTRACT

An optical module includes a wiring substrate, electronic components mounted on the wiring substrate, and a waveguide component mounted on the wiring substrate and connecting the electronic components to each other. The waveguide component includes a waveguide substrate including an optical waveguide, a first surface, and a second surface opposite the first surface. A photonic integrated circuit element is mounted on the first surface of the waveguide substrate and optically connected to the optical waveguide. An electrical integrated circuit element is mounted on the second surface of the waveguide substrate and electrically connected to the photonic integrated circuit element.

### CROSS-REFERENCE TO RELATED APPLICATIONS

This application is based upon and claims the benefit of priority from prior Japanese Patent Application No. 2024-146392, filed on Aug. 28, 2024, the entire contents of which are incorporated herein by reference.

### BACKGROUND

### 1. Field

The present disclosure relates to an optical module and a method for manufacturing an optical module.

### 2. Description of Related Art

A typical optical module used for optical communication includes a wiring substrate, an optical waveguide stacked on the wiring substrate, an optical element mounted on the wiring substrate, and an electronic component mounted on the wiring substrate. JP2021-018409A describes one example of an optical module.

### SUMMARY OF THE DISCLOSURE

In accordance with the typical optical module for optical communication described above, when the number of components mounted on the wiring substrate increases, the yield of the optical modules may decrease.

In one general aspect, an optical module includes a wiring substrate, electronic components mounted on the wiring substrate, and a waveguide component mounted on the wiring substrate and connecting the electronic components to each other. The waveguide component includes a waveguide substrate, a photonic integrated circuit element, and an electrical integrated circuit element. The waveguide substrate includes an optical waveguide, a first surface, and a second surface opposite the first surface. The photonic integrated circuit element is mounted on the first surface of the waveguide substrate and optically connected to the optical waveguide. The electrical integrated circuit element is mounted on the second surface of the waveguide substrate and electrically connected to the photonic integrated circuit element.

Other features and aspects will be apparent from the following detailed description, the drawings, and the claims.

### BRIEF DESCRIPTION OF THE DRAWINGS

FIG. 1 is a schematic perspective view of an optical module in accordance with a first embodiment.

FIG. 2 is a schematic cross-sectional view illustrating the optical module of FIG. 1.

FIG. 3 is an enlarged cross-sectional view illustrating in part the optical module of FIG. 2.

FIG. 4 is a flowchart illustrating one example of a method for manufacturing the optical module in accordance with the first embodiment.

FIGS. 5, 6, 7, 8, 9, 10, 11, and 12 are schematic cross-sectional views illustrating the method for manufacturing the optical module of FIG. 1.

FIG. 13 is a schematic cross-sectional view of an optical module in accordance with a second embodiment.

FIG. 14 is a schematic cross-sectional view illustrating a modified example of the optical module.

FIG. 15 is a schematic cross-sectional view illustrating a further modified example of the optical module.

Throughout the drawings and the detailed description, the same reference numerals refer to the same elements. The drawings may not be to scale, and the relative size, proportions, and depiction of elements in the drawings may be exaggerated for clarity, illustration, and convenience.

### DETAILED DESCRIPTION

This description provides a comprehensive understanding of the methods, apparatuses, and/or systems described. Modifications and equivalents of the methods, apparatuses, and/or systems described are apparent to one of ordinary skill in the art. Sequences of operations are exemplary, and may be changed as apparent to one of ordinary skill in the art, with the exception of operations necessarily occurring in a certain order. Descriptions of functions and constructions that are well known to one of ordinary skill in the art may be omitted.

Exemplary embodiments may have different forms, and are not limited to the examples described. However, the examples described are thorough and complete, and convey the full scope of the disclosure to one of ordinary skill in the art.

In this specification, “at least one of A and B” should be understood to mean “only A, only B, or both A and B.”

Embodiments will now be described with reference to the drawings. In the accompanying drawings, elements are illustrated for simplicity and clarity and have not necessarily been drawn to scale. In the cross-sectional views, to facilitate understanding of the cross-sectional structure of each member, hatching lines may be replaced by shadings or may not be illustrated. Further, unless otherwise specified, a numerical range of “X1 to X2,” which is specified by upper limit value X1 and lower limit value X2, refers to a range that is greater than or equal to X1 and less than or equal to X2.

### First Embodiment

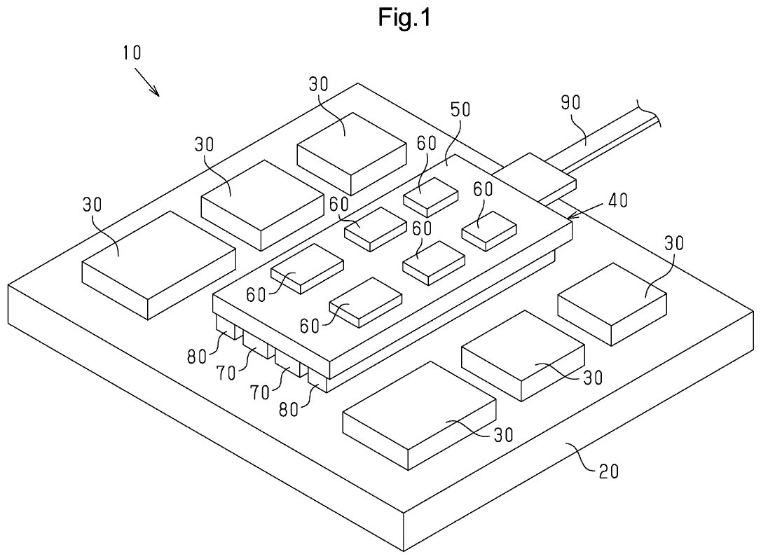

A first embodiment will now be described with reference to FIGS. 1 to 12.

### Overall Structure of the Optical Module 10

As illustrated in FIG. 1, an optical module 10 includes a wiring substrate 20, one or more (e.g., six) electronic components 30 mounted on the wiring substrate 20, and a waveguide component 40 mounted on the wiring substrate 20. The optical module 10 includes, for example, an optical fiber 90. Each electronic component 30 may be, for example, an IC chip incorporating a digital signal processor, an amplifier, or the like.

### Structure of the Wiring Substrate 20

The wiring substrate 20 has, for example, the form of a flat plate. The wiring substrate 20 is, for example, rectangular in plan view. The waveguide component 40 and the electronic components 30 are mounted on the wiring substrate 20. Elements other than the waveguide component 40 and the electronic components 30, for example, optical functional elements, may be mounted on the wiring substrate 20. Examples of an optical functional element include a light-emitting element, an optical modulator, an optical amplifier, and an optical attenuator.

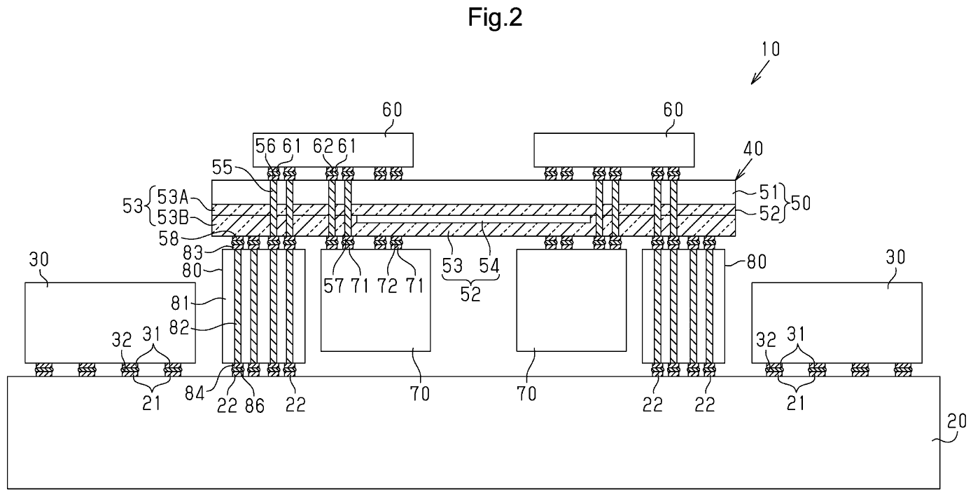

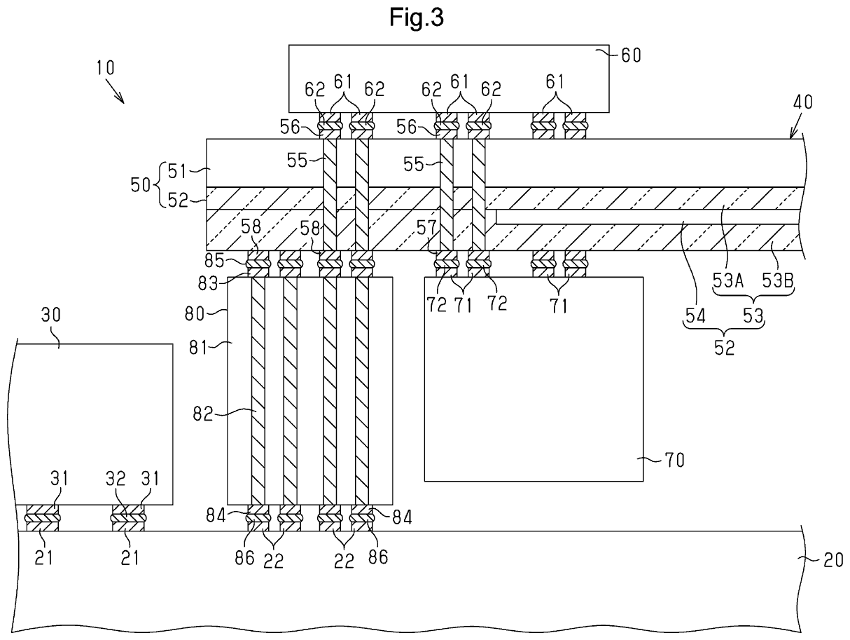

As illustrated in FIGS. 2 and 3, the wiring substrate 20 includes connection pads 21 and connection pads 22. The connection pads 21 and 22 are arranged on the wiring substrate 20. The connection pads 21 are electronic component connection pads electrically connected to the electronic components 30. The connection pads 22 are waveguide component connection pads electrically connected to the waveguide component 40. Although not illustrated in the drawings, the wiring substrate 20 includes, for example, wiring electrically connecting the connection pads 21 and the connection pads 22.

### Structure of the Electronic Components 30

As illustrated in FIG. 3, each electronic component 30 includes electrode pads 31 formed on the lower surface of the electronic component 30. Each electronic component 30 is mounted on the upper surface of the wiring substrate 20. Each electronic component 30 is, for example, flip-chip mounted on the connection pads 21 of the wiring substrate 20. For example, the electrode pads 31 of each electronic component 30 are electrically connected by a solder layer 32 to the connection pads 21 of the wiring substrate 20. Thus, each electronic component 30 is electrically connected by the electrode pads 31 and the solder layer 32 to the connection pads 21. The electronic components 30 are connected to one another by, for example, wiring in the wiring substrate 20 and by the waveguide component 40.

### Structure of the Waveguide Component 40

As illustrated in FIG. 1, the waveguide component 40 includes a waveguide substrate 50 and one or more electrical integrated circuits (EIC) elements 60 mounted on the upper surface of the waveguide substrate 50. The waveguide component 40 includes one or more photonic integrated circuit (PIC) elements 70 mounted on the lower surface of the waveguide substrate 50. The waveguide component 40 of the first embodiment includes six EIC elements 60 and six PIC elements 70 (only two illustrated in FIG. 1). The waveguide component 40 includes, for example, one or more (e.g., two) supports 80 mounted on the waveguide substrate 50.

Each PIC element 70 includes an optical circuit. The optical circuit includes, for example, an optical element and an optical modulation circuit. Examples of the optical element include, for example, a light-receiving element such as a photodiode or an avalanche photodiode. Each EIC element 60 includes, for example, an electrical circuit electrically connected to the optical circuits of the PIC elements 70, and a signal processing circuit that performs high-speed signal-processing with the electronic components 30. The electrical circuit includes, for example, an electronic circuit such as a driver that drives the optical elements of the optical circuits, an impedance conversion amplifier that converts photocurrent generated by the optical circuits to voltage signals, or the like. The signal processing circuit includes, for example, a digital-analog converter and an analog-digital converter. Each EIC element 60 generates more heat than each PIC element 70. Each PIC element 70 is, for example, thicker than each EIC element 60.

The waveguide component 40 connects the electronic components 30 to one another. The waveguide component 40, for example, connects the electronic components 30 to one another through optical signals and electrical signals.

### Structure of the Waveguide Substrate 50

As illustrated in FIG. 3, the waveguide substrate 50 includes a base 51 and one or more optical waveguides 52 formed on the base 51. The optical waveguide 52 is, for example, optically connected to the PIC elements 70. The optical waveguide 52 includes a cladding layer 53 and a core layer 54. The optical waveguide 52 may be, for example, a silicon waveguide or a glass waveguide. The optical waveguide 52 of the first embodiment is a silicon waveguide.

The base 51 has, for example, the form of a flat plate. The base 51 is, for example, rectangular in plan view. The material of the base 51 may be, for example, silicon (Si) or silicon nitride (SiN).

The cladding layer 53 is arranged on the lower surface of the base 51. The cladding layer 53, for example, covers the lower surface of the base 51. The material of the cladding layer 53 may be, for example, silicon oxide (SiO₂) or the like.

The cladding layer 53 includes a first cladding layer 53A formed on the lower surface of the base 51, and a second cladding layer 53B formed on the lower surface of the first cladding layer 53A so as to cover the core layer 54. In the drawings, to clearly depict the first cladding layer 53A and the second cladding layer 53B, a solid line is drawn between the first cladding layer 53A and the second cladding layer 53B. In the actual waveguide component 40, there may be no boundary between the first cladding layer 53A and the second cladding layer 53B. Otherwise, the boundary may not be clear.

Optical signals propagate through the core layer 54. The core layer 54 is embedded in the cladding layer 53. The core layer 54 is entirely encompassed by the cladding layer 53. The core layer 54 is formed on the lower surface of the first cladding layer 53A. The upper surface of the core layer 54 is entirely covered by the first cladding layer 53A. The side surfaces and lower surface of the core layer 54 are entirely covered by the second cladding layer 53B. The core layer 54, for example, extends parallel to the lower surface of the base 51. Optical signals propagate through only the core layer 54. Thus, the core layer 54 is formed from a material having a higher refractive index than the cladding layer 53, which is formed from SiO₂. The material of the core layer 54 may be, for example, Si. The light entering the core layer 54 propagates in a propagation direction that is in conformance with the planar shape of the core layer 54.

The waveguide component 40 includes through-vias 55 extending through the waveguide substrate 50 in a thickness direction, pads 56 arranged on the upper surface of the waveguide substrate 50, and pads 57 and 58 arranged on the lower surface of the waveguide substrate 50.

Each through-via 55 extends through the base 51 in a thickness direction and extends through the cladding layer 53 in a thickness direction. Each through-via 55 extends through the first cladding layer 53A and through the second cladding layer 53B in the thickness direction. Each through-via 55, for example, fills a through hole extending through the waveguide substrate 50 in a thickness direction.

Each pad 56 is arranged on the upper surface of the base 51. Each pad 56 is electrically connected to one of the through-vias 55. The pads 56 are EIC element connection pads connected to the EIC elements 60.

The pads 57 and 58 are each arranged on the lower surface of the second cladding layer 53B. The pads 57 and 58 are each connected to one of the pads 56 by the corresponding through-via 55. Each pad 57 is a PIC element connection pad electrically connected to one of the PIC elements 70. Each pad 58 is a support connection pad electrically connected to one of the supports 80.

### Structure of the EIC Elements 60

Each EIC element 60 includes electrode pads 61 formed on the lower surface of the EIC element 60. Each EIC element 60 is mounted on the upper surface of the waveguide substrate 50. Each EIC element 60 is, for example, flip-chip-mounted on the corresponding pads 56 of the waveguide substrate 50. For example, the electrode pads 61 of each EIC element 60 are electrically connected by a solder layer 62 to the pads 56 of the waveguide substrate 50. Thus, each EIC element 60 is electrically connected by the electrode pads 61 and the solder layer 62 to the pads 56.

### Structure of the PIC Elements 70

Each PIC element 70 includes electrode pads 71 formed on the upper surface of the PIC element 70. Each PIC element 70 is mounted on the lower surface of the waveguide substrate 50. In this manner, each EIC element 60 is mounted on the upper surface of the waveguide substrate 50, and each PIC element 70 is mounted on the opposite lower surface of the waveguide substrate 50. Each PIC element 70 is, for example, flip-chip mounted on the corresponding pads 57 of the waveguide substrate 50. For example, the electrode pads 71 of each PIC element 70 are electrically connected by a solder layer 72 to the pads 57 of the waveguide substrate 50. Thus, each PIC element 70 is electrically connected by the electrode pads 71 and the solder layer 72 to the pads 57. Further, the electrode pads 71 of each PIC element 70 are electrically connected by the solder layer 72, the pads 57, the through-vias 55, the pads 56, and the solder layer 62 to the electrode pads 61 of one of the EIC elements 60. In this manner, the PIC elements 70 are electrically connected to the EIC elements 60 over a relatively short distance by the through-vias 55, which extend through the waveguide substrate 50 in the thickness device. Each PIC element 70 overlaps the corresponding EIC element 60 in plan view. This connects the PIC element 70 to the EIC element 60 through a straight path extending through the waveguide substrate 50 in the thickness direction.

### Structure of the Supports 80

Each support 80 includes a main body 81, through-vias 82 extending through the main body 81 in a thickness direction, connection pads 83 arranged on the upper surface of the main body 81, and connection pads 84 arranged on the lower surface of the main body 81.

The main body 81 is, for example, beam-shaped and extends in the vertical direction as viewed in FIG. 2. The main body 81 is thicker than the PIC elements 70. The main body 81 is, for example, a dielectric. The material of the main body 81 may be, for example, a ceramic such as aluminum oxide (Al₂O₃) or aluminum nitride (AlN).

Each through-via 82, for example, fills a through hole extending through the main body 81 in the thickness direction. Each connection pad 83 is electrically connected to one of the through-vias 82. The connection pads 83 are waveguide substrate connection pads electrically connected to the waveguide substrate 50. Each connection pad 83 is electrically connected to one of the pads 58 of the waveguide substrate 50. Each connection pad 84 is electrically connected by one of the through-vias 82 to the corresponding connection pad 83. The connection pads 84 are wiring substrate connection pads electrically connected to the wiring substrate 20. Each connection pad 84 is electrically connected to one of the connection pads 22 of the wiring substrate 20.

Each support 80 is mounted on the lower surface of the waveguide substrate 50. In this manner, the supports 80 are mounted together with the PIC elements 70 on the lower surface of the waveguide substrate 50. Each support 80 is mounted on the lower surface of the waveguide substrate 50 by bonding the connection pads 83 to the pads 58 of the waveguide substrate 50. For example, the connection pads 83 of the supports 80 are electrically connected by a solder layer 85 to the pads 58 of the waveguide substrate 50. Thus, the supports 80 are electrically connected by the connection pads 83 and the solder layer 85 to the pads 58. Further, the connection pads 83 of each support 80 are electrically by the solder layer 85, the pads 58, the through-vias 55, the pads 56, and the solder layer 62 to the electrode pads 61 of the corresponding EIC element 60. In this manner, the supports 80 are electrically connected to the EIC elements 60 over a relatively short distance by the through-vias 55, which extend through the waveguide substrate 50 in the thickness direction. Each support 80 overlaps the corresponding EIC elements 60 in plan view. This connects the support 80 to each EIC element 60 through a straight line extending through the waveguide substrate 50 in the thickness direction.

As illustrated in FIG. 2, the waveguide component 40 is mounted on the upper surface of the wiring substrate 20. The two supports 80 are mounted on the connection pads 22 of the wiring substrate 20 to support the waveguide component 40 on the upper surface of the wiring substrate 20. The connection pads 84 are bonded to the connection pads 22 to mount the waveguide component 40 on the wiring substrate 20. As illustrated in FIG. 3, the connection pads 84 of each support 80 are electrically connected by a solder layer 86 to the connection pads 22 of the wiring substrate 20. Thus, the supports 80 are electrically connected by the connection pads 84 and the solder layer 86 to the connection pads 22. In this manner, the EIC elements 60 of the waveguide component 40 are electrically connected by the through-vias 55 of the waveguide substrate 50, the through-vias 82 of the supports 80, the connection pads 22 of the wiring substrate 20, and the like to the electronic components 30. This electrically connects the electronic components 30 to one another through the waveguide component 40.

A gap extends between the lower surface of each PIC element 70 and the upper surface of the wiring substrate 20. In other words, in the waveguide component 40, the supports 80 are thicker than the PIC elements 70 so that a gap extends between the lower surface of each PIC element 70 and the upper surface of the wiring substrate 20.

### Structure of the Optical Fiber 90

As illustrated in FIG. 1, the optical fiber 90 is connected to the waveguide component 40. The optical fiber 90 is optically connected to the optical waveguide 52 of the waveguide substrate 50 (refer to FIG. 3). Although not illustrated in the drawings, the optical fiber 90 is, for example, arranged so that the optical axis of the core of the optical fiber 90 coincides with the optical axis of the core layer 54 of the optical waveguide 52 (refer to FIG. 3). The optical fiber 90 is, for example, a single-mode fiber.

In the optical module 10, optical signals from the optical fiber 90 propagate through the optical waveguide 52 of the waveguide substrate 50 (refer to FIG. 3). Optical signals are input from the optical waveguide 52 to the optical circuits of the PIC elements 70. The optical circuits generate photocurrent in accordance with the input optical signals. With reference to FIG. 3, the photocurrent is supplied through the through-vias 55, which extend through the waveguide substrate 50 in the thickness direction, to the electrical circuits of the EIC elements 60. The photocurrent is converted by the electrical circuits of the EIC elements 60 into voltage signals, which are further converted into digital signals by the signal processing circuits of the EIC elements 60. The digital signals are supplied through the through-vias 55 of the waveguide substrate 50, the through-vias 82 of the supports 80, the wiring in the wiring substrate 20, and the like to the electronic components 30.

### Method for Manufacturing the Optical Module 10

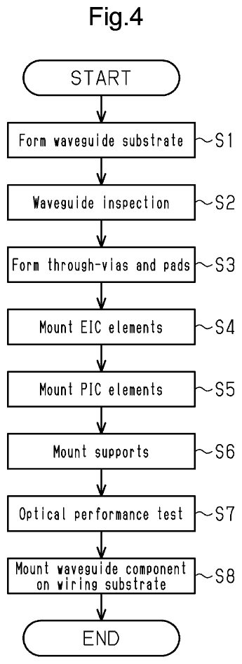

A method for manufacturing the optical module 10 will now be described with reference to FIG. 4. FIG. 4 is a flowchart illustrating one example of the method for manufacturing the optical module 10. To simplify illustration, elements that will ultimately become the final elements of the optical module 10 are given the same reference characters as the final elements.

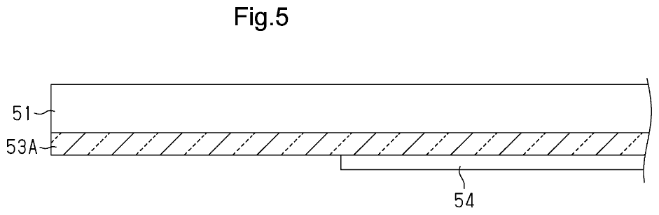

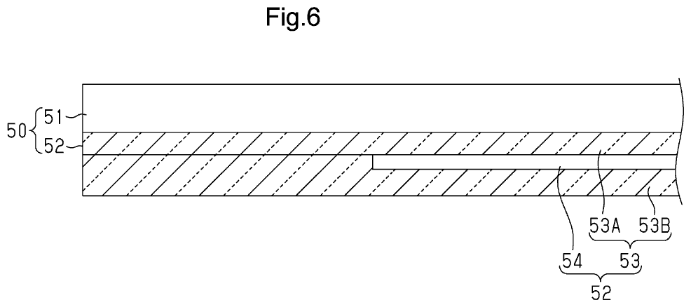

With reference to FIG. 4, in step S1, the waveguide substrate 50 is formed. For example, as illustrated in FIG. 5, the first cladding layer 53A is formed on the lower surface of the base 51, and the core layer 54 is formed on the lower surface of the first cladding layer 53A. Then, as illustrated in FIG. 6, the second cladding layer 53B, which covers the core layer 54, is formed on the lower surface of the first cladding layer 53A. The manufacturing steps described above form the optical waveguide 52 with the cladding layer 53, which includes the first cladding layer 53A and the second cladding layer 53B, and the core layer 54 on the lower surface of the base 51. This manufactures the waveguide substrate 50 that includes the optical waveguide 52.

Then, in step S2, which is illustrated in FIG. 4, a waveguide inspection is conducted to confirm that the optical waveguide 52 has been formed without defects. The waveguide inspection allows for determination of whether or not the optical waveguide 52 is defective. That is, the waveguide inspection allows for the selection of non-defective products from the manufactured waveguide substrates 50. The waveguide inspection is conducted by, for example, having light enter one longitudinal end of the optical waveguide 52 and checking whether the light exits the other longitudinal end of the optical waveguide 52 in a normal manner.

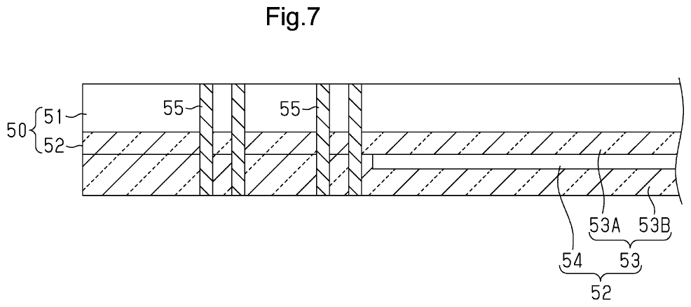

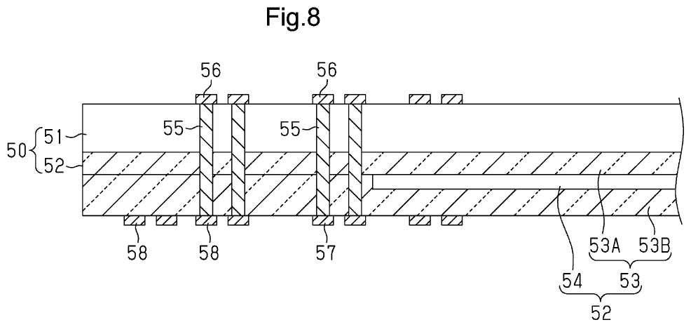

Then, in step S3, which is illustrated in FIG. 4, the through-vias 55 and the pads 56, 57, and 58 are formed in and on the waveguide substrate 50, which has been determined as being non-defective in the waveguide inspection. For example, as illustrated in FIG. 7, through holes are formed extending through the waveguide substrate 50 in the thickness direction, and the through holes are then filled with the through-vias 55. The through holes may be formed, for example, through laser processing using an excimer laser or a YAG laser. The through-vias 55 may be formed, for example, by performing an electrolytic plating process or by filling the through holes with a paste. Then, as illustrated in FIG. 8, the pads 56 are formed on the upper surface of the waveguide substrate 50, that is, the upper surface of the base 51. Further, the pads 57 and 58 are formed on the lower surface of the waveguide substrate 50; that is, the lower surface of the second cladding layer 53B. The pads 56, 57, and 58 are formed, for example, through a wiring formation process such as a semi-additive process or a subtractive process.

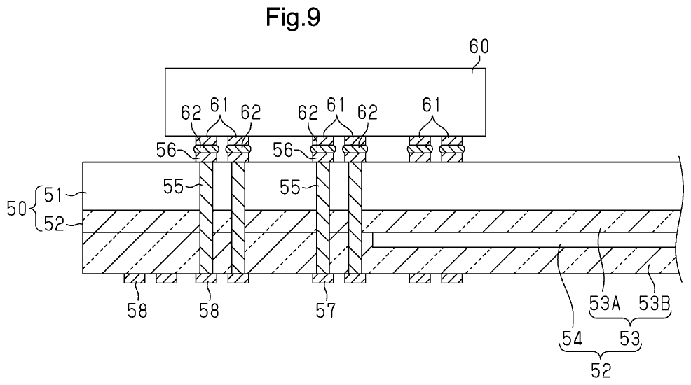

Then, in step S4, which is illustrated in FIG. 4, the EIC elements 60 are mounted on the waveguide substrate 50. For example, as illustrated in FIG. 9, the EIC elements 60 are mounted on the pads 56 of the waveguide substrate 50. In this case, the electrode pads 61 of the EIC elements 60 are bonded by the solder layer 62 onto the pads 56. For example, the waveguide substrate 50 and the EIC elements 60 are arranged in position and a reflow process is then performed to melt the solder layer 62. This electrically connects the electrode pads 61 to the pads 56 with the solder layer 62. The reflow process is performed at a temperature of, for example, approximately 260° C.

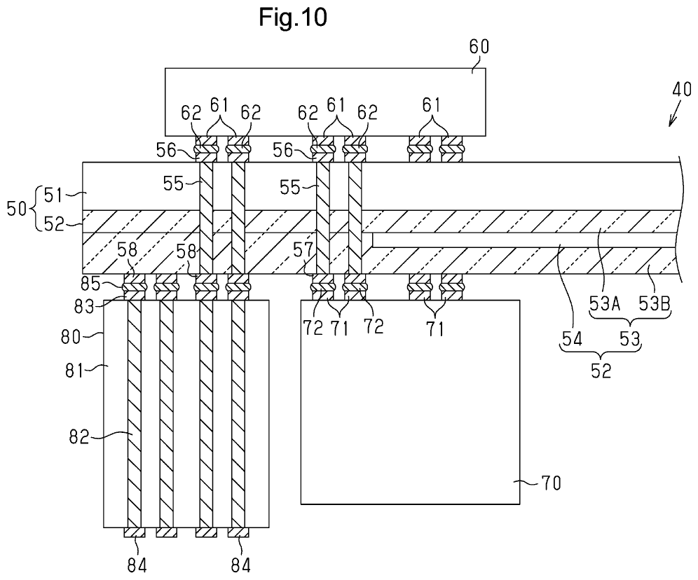

Then, in step S5, which is illustrated in FIG. 4, the PIC elements 70 are mounted on the waveguide substrate 50. Further, in step S6, the supports 80 are mounted on the waveguide substrate 50. For example, as illustrated in FIG. 10, the PIC elements 70 are mounted on the pads 57 of the waveguide substrate 50, and the supports 80 are mounted on the pads 58 of the waveguide substrate 50. For example, in the same manner as the step illustrated in FIG. 9, the electrode pads 71 of the PIC elements 70 are bonded by the solder layer 72 onto the pads 57, and the connection pads 83 of the supports 80 are bonded by the solder layer 85 onto the pads 58. In this step, the PIC elements 70 are mounted on the waveguide substrate 50 so that the optical waveguide 52 of the waveguide substrate 50 is optically connected to the PIC elements 70. Further, in this step, the EIC elements 60 are electrically connected to the PIC elements 70 by the through-vias 55, which extend through the waveguide substrate 50 in the thickness direction. The mounting of the supports 80 may be performed, for example, at the same time as when the PIC elements 70 are mounted or before the PIC elements 70 are mounted. Further, the mounting of the PIC elements 70 may be performed, for example, before the EIC elements 60 are mounted.

The manufacturing steps described above allows for the manufacturing of the waveguide component 40 including the waveguide substrate 50, which includes the optical waveguide 52, the EIC elements 60, which are mounted on the upper surface of the waveguide substrate 50, and the PIC elements 70 and the supports 80, which are mounted on the lower surface of the waveguide substrate 50.

Then, in step S7, which is illustrated in FIG. 4, an optical performance test (functional test) is conducted on the waveguide component 40. The optical performance test determines whether the performance and functionality of the waveguide component 40 are in accordance with the design specifications in order to determine whether or not the waveguide component 40 is defective. That is, the optical performance test allows for the selection of non-defective products from the manufactured waveguide components 40 (i.e., waveguide components 40 that are in accordance with design specifications). As illustrated in FIG. 10, the waveguide component 40 includes the optical waveguide 52, the PIC elements 70 optically connected to the optical waveguide 52, and the EIC elements 60 electrically connected to the PIC elements 70. Thus, for example, the optical connection between the optical waveguide 52 and the PIC elements 70 and the electrical connection between the PIC elements 70 and the EIC elements 60 may be checked to find defects before mounting the waveguide component 40 on the wiring substrate 20 (refer to FIG. 3). Thus, before mounting the waveguide component 40 on the wiring substrate 20, the electronic components 30 may be tested to determine whether their performance and functionalities are in accordance with the designed specifications.

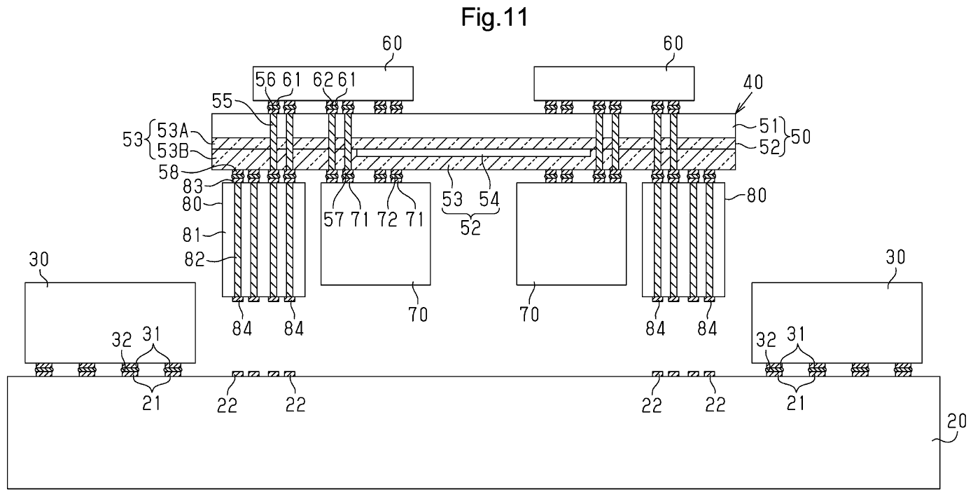

Then, in step S8, which is illustrated in FIG. 4, the waveguide component 40, which has been determined as being non-defective in the optical performance test, is mounted on the wiring substrate 20. For example, as illustrated in FIG. 11, the wiring substrate 20, which includes the connection pads 21 and 22, is first prepared. Then, the electronic components 30 are mounted on the connection pads 21. For example, in the same manner as the step illustrated in FIG. 9, the electrode pads 31 of the electronic components 30 are bonded by the solder layer 32 onto the connection pads 21. Then, the waveguide component 40, which has been determined as being non-defective in the optical performance test, is arranged above the wiring substrate 20. In this state, the waveguide component 40 and the wiring substrate 20 are positioned so that the connection pads 84 of the supports 80 on the waveguide component 40 are aligned in the vertical direction with the connection pads 22 of the wiring substrate 20.

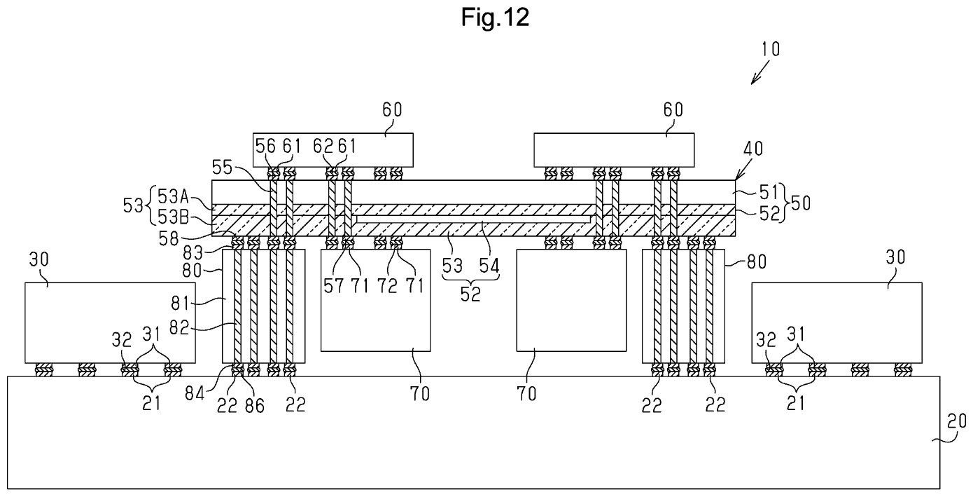

Then, as illustrated in FIG. 12, the waveguide component 40 is mounted on the connection pads 22 of the wiring substrate 20. For example, in the same manner as the step illustrated in FIG. 9, the connection pads 84 of the supports 80 are bonded by the solder layer 86 onto the connection pads 22. The optical module 10 is manufactured through the manufacturing steps described above.

### Advantages of the First Embodiment

(1-1) The optical module 10 includes the wiring substrate 20, the electronic components 30 mounted on the wiring substrate 20, and the waveguide component 40 mounted on the wiring substrate 20 and electrically connecting the electronic components 30 to one another. The waveguide component 40 includes the optical waveguide 52, the waveguide substrate 50 including a first surface (i.e., lower surface) and a second surface (i.e., upper surface), and the PIC elements 70 mounted on the lower surface of the waveguide substrate 50 and optically connected to the optical waveguide 52. The waveguide component 40 includes the EIC elements 60 mounted on the upper surface of the waveguide substrate 50 and electrically connected to the PIC elements 70.

In this structure, the waveguide component 40, which is mounted on the wiring substrate 20, includes the optical waveguide 52, the PIC elements 70 optically connected to the optical waveguide 52, and the EIC elements 60 electrically connected to the PIC elements 70. This allows the optical performance test to be conducted on the waveguide component 40 before it is mounted on the wiring substrate 20. Thus, before the waveguide component 40 is mounted on the wiring substrate 20, the optical connection between the optical waveguide 52 and the PIC elements 70 and the electrical connection between the PIC elements 70 and the EIC elements 60 may be checked to find defects and determine whether the performance and functionality of the waveguide component 40 are in accordance with the designed specifications. Accordingly, the waveguide component 40, including the EIC elements 60 and the PIC elements 70, has to pass the optical performance test and be determined as being non-defective to be mounted on the wiring substrate 20. As a result, even when there is an increase in the number of components mounted on the wiring substrate 20, the final yield of the optical modules 10 will be unaffected.

(1-2) In the conventional optical module, the optical connection of an optical element and an optical waveguide is performed after mounting the optical element on a wiring substrate. Thus, an operational test, such as an optical performance test, is conducted after components are mounted on the wiring substrate. Accordingly, in the conventional optical module, defects found during the operational test, such as an optical performance test, will decrease the product yield. In this regard, the optical module 10 in accordance with the first embodiment allows an operational test, such as an optical performance test, to be performed on the waveguide component 40 before it is mounted on the wiring substrate 20. This determines whether the waveguide component 40 is non-defective before it is mounted on the wiring substrate 20. The waveguide component 40 is allowed to be mounted on the wiring substrate 20 only when the waveguide component 40 is determined as being non-defective. As a result, the effect of optical performance tests on the yield of the optical modules 10 will be limited.

(1-3) The waveguide component 40 includes the through-vias 55, which extend through the waveguide substrate 50 in the thickness direction, and the pads 57, which are formed on the lower surface of the waveguide substrate 50 and electrically connected to the through-vias 55. Further, the waveguide component 40 includes the pads 56 formed on the upper surface of the waveguide substrate 50 and electrically connected by the through-vias 55 to the pads 57. The PIC elements 70 are mounted on the pads 57. The EIC elements 60 are mounted on the pads 56.

This structure electrically connects the PIC elements 70 to the EIC elements 60 with the through-vias 55 extending through the waveguide substrate 50 in the thickness direction. Thus, the wiring length between the PIC elements 70 and the EIC elements 60 is shorter than when the PIC elements 70 are arranged beside the EIC elements 60 on the same plane. This improves the electrical characteristics of the optical module 10. For example, high-frequency loss is reduced, transmission quality is improved, and electric power consumption is reduced.

(1-4) The wiring substrate 20 includes the connection pads 21, which are electrically connected to the electronic components 30, and the connection pads 22, which are electrically connected to the waveguide component 40 and electrically connected to the connection pads 21. Further, the waveguide component 40 includes the pads 58, which are formed on the lower surface of the waveguide substrate 50 and electrically connected to the connection pads 22. The EIC elements 60 are arranged overlapping the PIC elements 70 in plan view and overlapping the pads 58 in plan view.

In this structure, the EIC elements 60 are arranged partially overlapping the PIC elements 70 in plan view. This limits enlargement of the optical module 10 in the planar direction (i.e., direction orthogonal to the thickness direction of the waveguide substrate 50) as compared with when the EIC elements 60 do not overlap the PIC elements 70 in plan view.

(1-5) The supports 80 each include the main body 81 including a first surface (upper surface) and a fourth surface (lower surface). The supports 80 each include the through-vias 82, which extend through the main body 81 in the thickness direction, and the connection pads 83, which are formed on the upper surface of the main body 81 and electrically connected to the through-vias 82. Further, the supports 80 each include the connection pads 84, which are formed on the lower surface of the main body 81 and electrically connected by the through-vias 82 to the connection pads 83. The main body 81 is thicker than the PIC elements 70. The supports 80 are mounted on the waveguide substrate 50 by bonding the connection pads 83 to the pads 58. The waveguide component 40 is mounted on the wiring substrate 20 by bonding the connection pads 84 to the connection pads 22.

In this structure, the main body 81 of each support 80 is thicker than the PIC elements 70. Thus, when mounting the waveguide component 40 on the wiring substrate 20, the PIC elements 70 do not interfere with the wiring substrate 20. Further, the pads 58 of the waveguide component 40 are electrically connected to the connection pads 22 of the wiring substrate 20 by the through-vias 82 extending through the supports 80 in the thickness direction. Thus, the wiring length between the pads 58 and the connection pads 22 will not be increased by the arrangement of the supports 80. As a result, the arrangement of the supports 80 will not adversely affect the electrical characteristics.

(1-6) The PIC elements 70 are mounted on the lower surface of the waveguide substrate 50 facing the wiring substrate 20, and the EIC elements 60 are mounted on the upper surface of the waveguide substrate 50. Thus, the PIC elements 70, which generate less heat than the EIC elements 60, are accommodated in the space surrounded by the wiring substrate 20, the supports 80, and the waveguide substrate 50. This reduces the heat that accumulates in the space surrounded by the wiring substrate 20, the supports 80, and the waveguide substrate 50.

### Second Embodiment

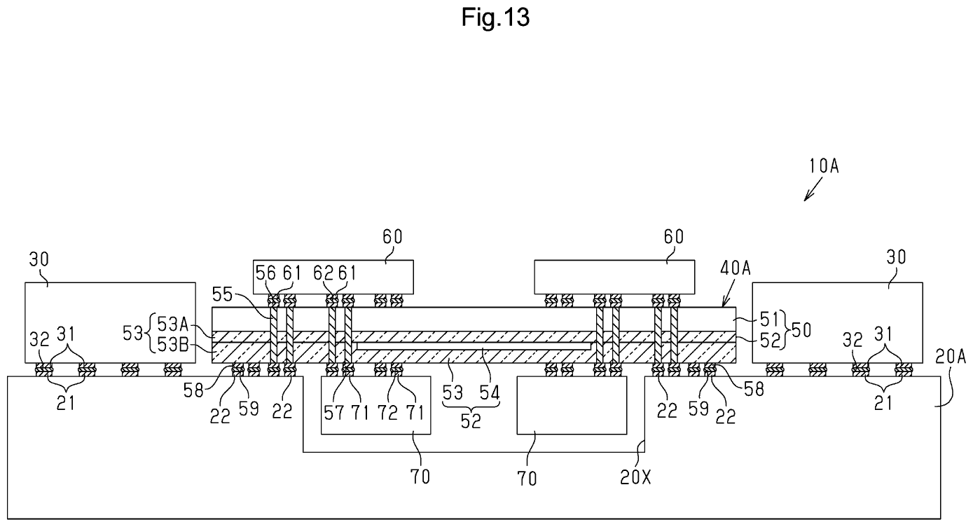

A second embodiment will now be described with reference to FIG. 13. The same reference numerals are given to those components that are the same as the corresponding components illustrated in FIGS. 1 to 12. Such components will not be described in detail. The description hereafter will focus on differences from the first embodiment.

As illustrated in FIG. 13, an optical module 10A in accordance with the present embodiment includes a wiring substrate 20A, the electronic components 30 mounted on the wiring substrate 20A, and a waveguide component 40A mounted on the wiring substrate 20A.

### Structure of the Wiring Substrate 20A

The wiring substrate 20A includes a recess 20X and the connection pads 21 and 22. The recess 20X is recessed downward from the surface (upper surface) of the wiring substrate 20A on which the connection pads 21 and 22 are formed. The recess 20X is sized to allow for accommodation of the PIC elements 70 of the waveguide component 40A.

### Structure of the Waveguide Component 40A

The waveguide component 40A includes the waveguide substrate 50, the through-vias 55, the pads 56, 57, and 58, the EIC elements 60, which are mounted on the upper surface of the waveguide substrate 50, and the PIC elements 70, which are mounted on the lower surface of the waveguide substrate 50. The waveguide component 40A in accordance with the second embodiment does not include the supports 80 of the waveguide component 40 in the first embodiment.

The waveguide component 40A is mounted on the upper surface of the wiring substrate 20A. The waveguide component 40A is mounted on the upper surface of the wiring substrate 20A by bonding the pads 58, which are arranged on the lower surface of the waveguide substrate 50, to the connection pads 22 of the wiring substrate 20A. For example, the pads 58 of the waveguide component 40A are electrically connected by a solder layer 59 to the connection pads 22 of the wiring substrate 20A. This electrically connects the EIC elements 60 of the waveguide component 40A to the connection pads 22 of the wiring substrate 20A through the electrode pads 61, the solder layer 62, the pads 56, the through-vias 55, the pads 58, and the solder layer 59.

The waveguide component 40A is, for example, mounted on the wiring substrate 20A so that the PIC elements 70 are accommodated in the recess 20X. The recess 20X has a depth that is greater than the thickness of each PIC element 70. This forms a gap extending between the lower surface of each PIC element 70 and the bottom surface of the recess 20X.

In addition to advantages (1-1) to (1-4) of the first embodiment, the second embodiment has the advantages described below.

(2-1) The upper surface of the wiring substrate 20A on which the connection pads 21 and 22 are formed includes the recess 20X. The depth of the recess 20X is greater than the thickness of the PIC elements 70. The waveguide component 40A is mounted on the wiring substrate 20A so that the PIC elements 70 are accommodated in the recess 20X.

In this structure, the depth of the recess 20X is greater than the thickness of the PIC elements 70. Thus, when mounting the waveguide component 40A on the wiring substrate 20A, the PIC elements 70 do not interfere with the wiring substrate 20A. This restricts contact between the lower surfaces of the PIC elements 70 and the bottom surface of the recess 20X.

(2-2) The pads 58 of the waveguide component 40 are bonded to the connection pads 22 of the wiring substrate 20A. This structure allows the wiring length between the pads 58 and the connection pads 22 to be shorter than when the supports 80 are provided. Thus, the electrical characteristics of the optical module 10 is improved.

### Modified Examples

The above embodiments may be modified as described below. The above-described embodiments and the modified examples described below may be combined as long as there is no technical contradiction.

The supports 80 of the first embodiment may have any structure.

The optical module 10 of the first embodiment includes two supports 80. Instead, the optical module 10 may include a single support 80 having a closed shape. In this case, the supports 80 surround the periphery of the PIC elements 70.

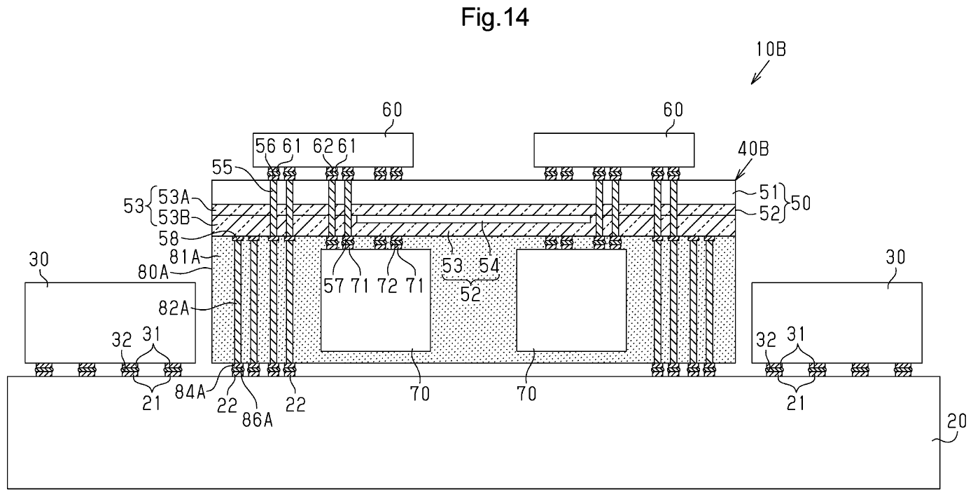

The optical module 10 of FIG. 2 may be modified to, for example, an optical module 10B illustrated in FIG. 14. The optical module 10B includes a waveguide component 40B, and the waveguide component 40B includes a support 80A formed on the lower surface of the waveguide substrate 50. The support 80A includes an encapsulation resin 81A formed on the lower surface of the waveguide substrate 50 and encapsulating the PIC elements 70. The encapsulation resin 81A is thicker than the PIC elements 70. The encapsulation resin 81A entirely covers the surfaces of the PIC elements 70. The encapsulation resin 81A entirely covers the upper surface, the side surfaces, and the lower surface of each PIC element 70. The encapsulation resin 81A encapsulates the pads 57 and 58. The encapsulation resin 81A covers the lower surface of the waveguide substrate 50. The encapsulation resin 81A fills the gap between the lower surface of the waveguide substrate 50 and the upper surface of each PIC element 70.

The material of the encapsulation resin 81A may be, for example, a non-photosensitive insulative resin of which the main component is a thermosetting resin. The material of the encapsulation resin 81A may be, for example, an insulative resin, such as an epoxy resin or a polyimide resin, or a resin material prepared by mixing such a resin with a filler, such as silica or alumina. The encapsulation resin 81A may be, for example, a molding resin.

The support 80A includes through-vias 82A, which extend through the encapsulation resin 81A in the thickness direction, and connection pads 84A, which are arranged on the lower surface of the encapsulation resin 81A.

Each through-via 82A, for example, fills a through hole extending through the encapsulation resin 81A in the thickness direction and exposing part of the lower surface of the corresponding pad 58. The through-via 82A is electrically connected to the pad 58. The connection pads 84A are electrically connected by the through-vias 82A to the pads 58.

The waveguide component 40B is mounted on the upper surface of the wiring substrate 20. The waveguide component 40B is mounted on the upper surface of the wiring substrate 20 by mounting the support 80A on the connection pads 22 of the wiring substrate 20. The waveguide component 40B is mounted on the wiring substrate 20 by bonding the connection pads 84A of the support 80A to the connection pads 22. The connection pads 84A of the support 80A are electrically connected by a solder layer 86A to the connection pads 22. In this manner, the EIC elements 60 of the waveguide component 40B are electrically connected by the through-vias 55 of the waveguide substrate 50, the through-vias 82A of the support 80A, the connection pads 22 of the wiring substrate 20, and the like to the electronic components 30.

The waveguide substrate 50 of the above embodiments may have any structure. For example, the base 51 may be omitted.

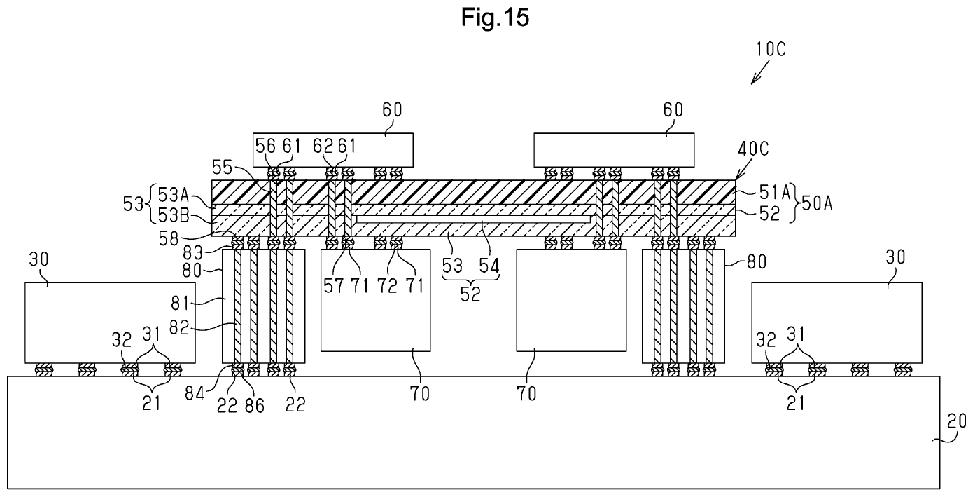

The optical module 10 of FIG. 2 may be modified to, for example, an optical module 10C illustrated in FIG. 15. The optical module 10C includes a waveguide component 40C, and the waveguide component 40C includes a waveguide substrate 50A. The waveguide substrate 50A includes a support substrate 51A and the optical waveguide 52, which is formed on the support substrate 51A.

The support substrate 51A has, for example, greater rigidity than the optical waveguide 52. The support substrate 51A may be formed by, for example, impregnating a woven cloth or non-woven cloth of glass fibers, aramid fibers, or the like with an insulative resin such as an epoxy resin.

The optical waveguide 52 of the present modified example is, for example, a polymer optical waveguide. In this case, the material of the cladding layer 53 and the core layer 54 may be an acrylic resin, such as polymethylmethacrylate (PMMA), an epoxy resin, or a silicone resin. In order for optical signals to propagate through only the core layer 54, the material of the core layer 54 has a higher refractive index than the material of the cladding layer 53.

With this structure, the support substrate 51A increases the rigidity of the waveguide substrate 50A. This allows the optical waveguide 52 formed on the lower surface of the support substrate 51A to be thin.

In each of the optical modules 10 and 10A of the above embodiments, the optical component connected to the waveguide components 40 and 40A is the optical fiber 90. Instead, for example, the optical component connected to the waveguide components 40 and 40A may be an optical connector. In this case, the optical connector is, for example, bonded to the waveguide components 40 and 40A. The optical connector is, for example, connectable to an external optical component or to an external light source. For example, the optical connector is attachable in a removable manner to a mating connector arranged on the end of an optical fiber.

In each of the optical modules 10 and 10A of the above embodiments, an underfill resin may be provided to fill the gap between the lower surface of the waveguide substrate 50 and the PIC elements 70.

In each of the optical modules 10 and 10A of the above embodiments, a heat dissipation component such as a heat sink may be mounted on the upper surface of each EIC element 60.

In the first embodiment, there is no limitation to how the supports 80 are mounted.

In each of the above embodiments, the EIC elements 60 are flip-chip mounted on the waveguide substrate 50. Instead, for example, the EIC elements 60 may be mounted on the waveguide substrate 50 through wire bonding or with solder.

In each of the above embodiments, the PIC elements 70 are flip-chip mounted on the waveguide substrate 50. Instead, for example, the PIC elements 70 may be mounted on the waveguide substrate 50 through wire bonding or with solder.

In each of the above embodiments, the electronic components 30 are flip-chip mounted on the wiring substrate 20. Instead, for example, the electronic components 30 may be mounted on the wiring substrate 20 through wire bonding or with solder.

In each of the optical modules 10 and 10A of the above embodiments, the electronic components 30, the EIC elements 60, and the PIC elements 70 are not limited in number.

In each of the optical modules 10 and 10A of the above embodiments, the mounting positions of the EIC elements 60 may be exchanged with the PIC elements 70. That is, the PIC elements 70 may be mounted on the upper surface of the waveguide substrate 50, and the EIC elements 60 may be mounted on the lower surface of the waveguide substrate 50.

### CLAUSES

This disclosure further encompasses the following embodiments.

1. A method for manufacturing an optical module, the method including:
forming a waveguide substrate including an optical waveguide, a first surface, and a second surface opposite the first surface;
conducting a waveguide inspection on the waveguide substrate;
mounting an electrical integrated circuit element on the second surface of the waveguide substrate;
mounting, on the first surface of the waveguide substrate, a photonic integrated circuit element optically connected to the optical waveguide and electrically connected to the electrical integrated circuit element;
conducting an optical performance test on a waveguide component including the waveguide substrate, the electrical integrated circuit element, and the photonic integrated circuit element; and
mounting the waveguide component on the wiring substrate.

Various changes in form and details may be made to the examples above without departing from the spirit and scope of the claims and their equivalents. The examples are for the sake of description only, and not for purposes of limitation. Descriptions of features in each example are to be considered as being applicable to similar features or aspects in other examples. Suitable results may be achieved if sequences are performed in a different order, and/or if components in a described system, architecture, device, or circuit are combined differently, and/or replaced or supplemented by other components or their equivalents. The scope of the disclosure is not defined by the detailed description, but by the claims and their equivalents. All variations within the scope of the claims and their equivalents are included in the disclosure.

What is claimed is:

1. An optical module, comprising:
a wiring substrate;
electronic components mounted on the wiring substrate; and
a waveguide component mounted on the wiring substrate and connecting the electronic components to each other, wherein the waveguide component includes
a waveguide substrate including an optical waveguide, a first surface, and a second surface opposite the first surface,
a photonic integrated circuit element mounted on the first surface of the waveguide substrate and optically connected to the optical waveguide, and
an electrical integrated circuit element mounted on the second surface of the waveguide substrate and electrically connected to the photonic integrated circuit element.

2. The optical module according to claim 1, wherein:
the waveguide component includes
a first through-via extending through the waveguide substrate in a thickness direction,
a first pad formed on the first surface of the waveguide substrate and electrically connected to the first through-via, and
a second pad formed on the second surface of the waveguide substrate and electrically connected by the first through-via to the first pad;
the photonic integrated circuit element is mounted on the first pad; and
the electrical integrated circuit element is mounted on the second pad.

3. The optical module according to claim 2, wherein:
the wiring substrate includes a first connection pad electrically connected to one of the electronic components, and a second connection pad electrically connected to the waveguide component and electrically connected to the first connection pad;
the waveguide component includes a third pad electrically connected to the second connection pad; and
the electrical integrated circuit element overlaps the photonic integrated circuit element in plan view and overlaps the third pad in plan view.

4. The optical module according to claim 3, wherein:
the waveguide component includes a support arranged on the first surface of the waveguide substrate;
the third pad is formed on the first surface of the waveguide substrate;
the support is thicker than the photonic integrated circuit element; and
the support is mounted on the second connection pad.

5. The optical module according to claim 4, wherein:
the support includes
a main body including a third surface and a fourth surface opposite the third surface,
a second through-via extending through the main body in a thickness direction,
a third connection pad formed on the third surface of the main body and electrically connected to the second through-via, and
a fourth connection pad formed on the fourth surface of the main body and electrically connected by the second through-via to the third connection pad;
the main body is thicker than the photonic integrated circuit element;
the third connection pad is bonded to the third pad to mount the support on the waveguide substrate; and
the fourth connection pad is bonded to the second connection pad to mount the waveguide component on the wiring substrate.

6. The optical module according to claim 3, wherein the third pad is electrically connected by the first through-via to the second pad.

7. The optical module according to claim 4, wherein the support includes
an encapsulation resin formed on the first surface of the waveguide substrate to encapsulate the photonic integrated circuit element,
a third through-via extending through the encapsulation resin in a thickness direction and electrically connected to the third pad, and
a fifth connection pad bonded to the second connection pad and electrically connecting the second connection pad and the third through-via.

8. The optical module according to claim 3, wherein:
the wiring substrate includes a recess in a surface of the wiring substrate on which the first connection pad and the second connection pad are formed;
the recess has a depth that is greater than a thickness of the photonic integrated circuit element;
the waveguide component is mounted on the wiring substrate so that the photonic integrated circuit element is accommodated in the recess; and
the third pad is bonded to the second connection pad.

9. The optical module according to claim 1, further comprising an optical fiber optically connected to the optical waveguide.

10. The optical module according to claim 1, wherein:
the photonic integrated circuit element is a first photonic integrated circuit element;
the electrical integrated circuit element is a first electrical integrated circuit element;
the first electrical integrated circuit element overlaps the first photonic integrated circuit element in plan view and extends toward a first side edge of the waveguide substrate beyond the first photonic integrated circuit element in a first direction in plan view; and
the waveguide component further includes
a second photonic integrated circuit element mounted on the first surface of the waveguide substrate and optically connected to the optical waveguide, wherein the second photonic integrated circuit element is arranged adjacent to the first photonic integrated circuit element in a second direction opposite to the first direction, and
a second electrical integrated circuit element mounted on the second surface of the waveguide substrate and electrically connected to the second photonic integrated circuit element, wherein the second electrical integrated circuit element is arranged adjacent to the first electrical integrated circuit element in the second direction,
wherein the second electrical integrated circuit element overlaps the second photonic integrated circuit element in plan view and extends toward a second side edge of the waveguide substrate beyond the second photonic integrated circuit element in the second direction in plan view.

11. The optical module according to claim 1, wherein:
the waveguide substrate includes a support substrate and the optical waveguide formed on the support substrate; and
the support substrate has a rigidity that is greater than that of the optical waveguide.
